(19) United States
(12) Patent Application Publication
(10) Pub. No.: US 2012/0086119 A1
(43) Pub. Date: Apr. 12, 2012

(54) CHIP STACKED STRUCTURE

(75) Inventor: MING-CHE WU, NANTOU COUNTY (TW)

(73) Assignees: UNIVERSAL GLOBAL SCIENTIFIC INDUSTRIAL CO., LTD., Nantou County (TW); UNIVERSAL SCIENTIFIC INDUSTRIAL (SHANGHAI) CO., LTD., Shanghai (CN)

(21) Appl. No.: 13/073,025

(22) Filed: Mar. 28, 2011

(30) Foreign Application Priority Data
Oct. 8, 2010 (TW) 99134476

(51) Int. Cl. H01L 23/488

(52) U.S. Cl. 257/737; 257/E23.023

(57) ABSTRACT

A chip stacked structure is provided. The chip stacked structure includes a first die and a second die stacked on the first die. The first die has a plurality of connection structures each which has a through hole, a connection pad and a solder bump. The connection pad has a terminal connected to the through hole. The solder bump is disposed on the connection pad and located around the through hole. The second die has a plurality of through holes which are aligned and bonded to the solder bump respectively. The chip stacked structure may simplify the process and improve the process yield rate.

### BACKGROUND OF THE INVENTION

1. Field of the Invention

The present invention relates to a chip stacked structure; in particular, to a stack-based chip structure.

2. Description of Related Art

The industry of integrated circuit (IC) generally encompasses IC design, IC manufacture and chip test. The chip structure can directly influence the electrical feature, mechanical feature, thermal feature and photo feature of the IC itself, which plays an extremely critical role with regards to the stability of IC, therefore the chip structure and electronic devices are inseparable and become one kernel technique in the entire electronic industry.

In early days, the lead-frame based structure was a leading method in the field of transmission structure. As technologies evolve, chips require faster transmission speeds, slimmer and smaller sizes, more chip pins, so the substrate-based structure is now becoming the main stream in market. However, after striding into so-call “nanometer generation”, the chip process needs to deal with even greater number of pins and further reduced sizes, hence the promising flip chip structure gradually moves into focus and the application thereof becomes more comprehensive.

The stack-based chip structure can be also referred as three dimension (3D) structure which essentially creates a chip stack in a layer by layer fashion and then electrically connects the dies disposed in upper and lower layers. Such a structure enables a significant increase in chip density, wherein more than two times of ICs can be included within each unit area; however, this approach is subject to low yield rate and complex process, and the goal of mass production may be difficult to achieve.

### SUMMARY OF THE INVENTION

In view of the aforementioned disadvantages, one objective of the present invention is to provide a chip stacked structure which packs multiple dies in a stack approach by using the through-silicon via technology and solder bumps, and such a chip stacked structure is able to enhance the stability of multi-chip stack structure and simplify processes as well.

The present invention is directed to a chip stacked structure comprising a first die and a second die. The first die includes a plurality of first connection structures, each of the first connection structures having a first through hole, a first connection pad and a first solder bump, wherein one terminal of the first connection pad is connected to the first through hole and the first solder bump is disposed on the first connection pad and located around the first through hole. The second die is stacked on the top of the first die and includes a plurality of second connection structures, with each second connection structure having a second through hole. Herein, each second through hole in the second die is respectively aligned and bonded to each first solder bump in the first die.

In an embodiment of the present invention, each second connection structure further comprises a second connection pad and a second solder bump, the second connection pad is connected to the second through hole, and the second solder bump is disposed on the second connection pad and located around the second through hole.

In an embodiment of the present invention, the upper surface of the first die faces toward the lower surface of the second die, the first connection pad and the first solder bump are located on the upper surface of the first die, and the second connection pad and the second solder bump are located on the upper surface of the second die.

In an embodiment of the present invention, each first connection structure and each second connection structure are symmetrical in structure, and positions of such first connection structures and such second connection structures are mutually interlaced.

In an embodiment of the present invention, the first through hole and the second through hole are filled with a conductive material. The second through hole and the first solder bump are bonded by a heating process.

In an embodiment of the present invention, the aforementioned first connection structure is located on the edge of the first die, the aforementioned second connection structure is located on the edge of the second die, and such first connection structures respectively correspond to such second connection structures.

In an embodiment of the present invention, each first connection structure further comprises a third connection pad, wherein the first connection pad and the third connection pad are respectively disposed on an upper surface and a lower surface of the first die, and the third connection pad is connected to the first through hole.

In an embodiment of the present invention, the first connection pad is covered with a solder mask layer which has an opening for placing of the solder bump.

In summary, the chip stacked structure effectively enlarges the area for corresponding joint by using the connection pad and the solder bump, and a plurality of stacked chips can be simultaneously joined. Furthermore, the present invention advantageously enables the effects of process simplification and process yield rate elevation.

To better understand the characteristics and advantages of the present invention set forth previously, certain preferred embodiments thereof are hereunder provided, along with appended drawings, thereby facilitating detailed descriptions of the present invention.

### BRIEF DESCRIPTION OF THE DRAWINGS

FIG. 1 shows a diagram of the chip stacked structure according to a first embodiment of the present invention;

FIG. 2 shows a diagram of the connection structure according to the first embodiment of the present invention;

FIG. 3 shows a diagram of a local structure in the die 110 according to the first embodiment of the present invention; and

FIG. 4 shows a diagram of the connection structure according to a second embodiment of the present invention.

### DETAILED DESCRIPTION OF THE PREFERRED EMBODIMENTS

### First Embodiment

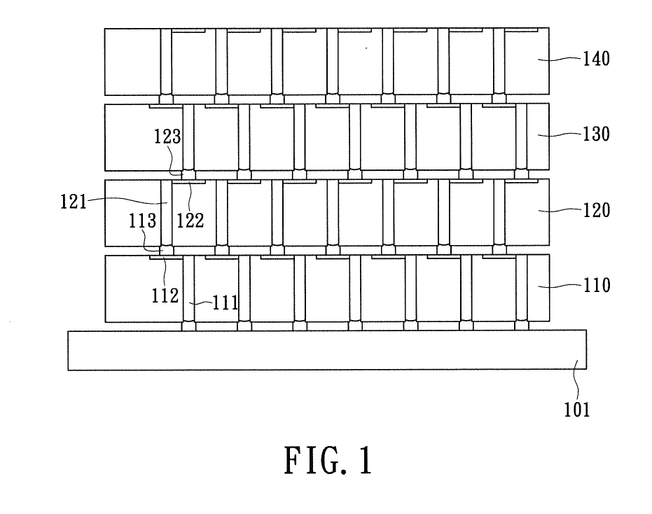

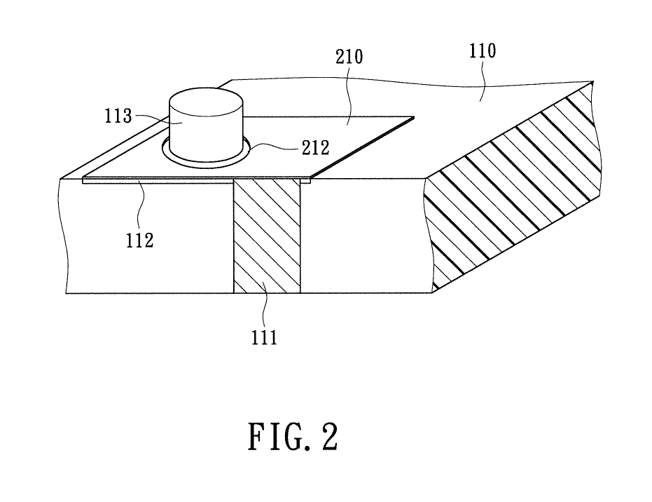

First of all, refer collectively to FIGS. 1 and 2, wherein FIG. 1 shows a diagram of the chip stacked structure according to a first embodiment of the present invention, and FIG. 2 shows a diagram of the connection structure according to the first embodiment of the present invention. The dies 110˜140 are disposed in a stack fashion, with each die comprising multiple connection structures for connecting to the die located in an upper layer. Taking the die 110 and 120 for example, the die 110 includes multiple connection structures, each connection structure having a through hole 111, a connection pad 112 and a solder bump 113 (also known as a solder ball). The through hole 111 is formed inside or on the edge of the die 110 by using the through-silicon via (TSV) technology, and the through hole 111 is filled with a conductive material thereby electrically connecting to the upper surface and lower surface of the die 110. The connection pad 112 is formed on the upper surface of the die 110 and connected to the through hole 111 in order to electrically connect thereto, wherein the area of the connection pad 112 is larger than the one of the through hole 111 and is sufficiently large for disposing the solder bump 113, as shown in FIG. 2. The solder bump 113 is configured on the connection pad 112, located around the through hole 111 and electrically connected to the through hole 111 by way of the connection pad 112. Furthermore, the connection pad 112 may be covered with a solder mask layer 210 which has an opening 212 for placing the solder bump 113. The solder bump 113 can be softened after being heated, and the edge thickness of the opening 212 can effectively restrict the softened solder bump 113 thereby preventing excessive extension of the softened solder bump 113. Due to surface tension, the softened solder bump 113 becomes drop-shaped and can be bonded with the corresponding through hole 121.

Similarly, the die 120 has multiple connection structures, with each connection structure including a through hole 121, a connection pad 122 and a solder bump 123, and whose structure is analogous to the one found in the die 110, thus descriptions thereof are omitted for brevity. The through hole 121 in the die 120 is correspondingly bonded with the solder bump 123 on the die 110 thereby allowing the die 120 to be electrically connected to the die 110. In connecting the dies 120 and 110, it needs only to place the die 120 on the top of the die 110, align the through hole 121 in position to the solder bump 113 on the die 110 and then heat the solder bump 113 in order to join the solder bump 113 with the through hole 121, thus completing the connection between the through hole 121 and the connection pad 112.

In packing multiple dies, the lower surface of a die (e.g., 120) in an upper layer faces toward the upper surface of a die (e.g., 110) in a lower layer, and then the multiple through holes 121 of the die 120 in the upper layer are respectively aligned in position to the multiple solder bumps 113 on the die 110 in the lower layer, thus connecting the through holes 121 to the solder bumps 123 in one single reflow process. Since the area of the connection pad 112 is larger than the one of the through hole 111, alignment thereof can be more conveniently performed; hence, connections among the dies 110˜140 can be achieved successfully even certain slight alignment errors therebetween may exist. Such a process can simplify the procedure of stack-based structure and also enhance the stability of manufacture processes.

In the present embodiment, the area of the connection pad 112 is larger than the one of the through hole 111, and the solder bump 113 is disposed on the connection pad 112 and located around the through hole 111. Therefore, in a process, it is not required to precisely align the through holes respectively located in the dies of upper layer and of lower layer; rather, it needs merely to make the through hole (e.g., 121) in the die of upper layer align to the solder bump (e.g., 113) in the die of lower layer and then perform subsequent heating and bonding processes. So, after stacking the chips, the through hole 121 in the die 120 and the through hole 111 in the die 110 can constitute an interlaced configuration, as shown in FIG. 1. Meanwhile, the connection structure of the dies 110 and 120 can present an alternating disposition as well.

It should be noted that a redistribution layer (RDL) can be formed on the upper surface or lower surface of the die 110, but the present invention is not limited thereto. The connection pad 112 on the die 110 can be electrically connected with each other or connected to the circuit components inside the die 110 by means of such a redistribution layer. The stack-based structure for the die 130, 140 is executed in the same way, and the number of dies is not limited. The orientation of the stack of dies 110˜140 can be also up-down reversed; for example, by means of the flip chip stack method, but the present invention is not limited thereto. The through hole 111, 121 can be directly formed on the die or a wafer using the through-silicon via technology. Besides, the technical means utilized in the present embodiment can be directly applied on the structure between a chip and a printed circuit board (PCB), wherein the die 110 can be installed on a PCB 101 (also referred as a substrate, such as ceramic substrate, glass substrate or plastic substrate), and the through hole 111 in the die 110 can be connected to the PCB 101 by means of solder bumps. Through the aforementioned descriptions on the present embodiment, those skilled ones in the present technical field are capable of inferring to other possible implementations whose illustrations are herein omitted for brevity.

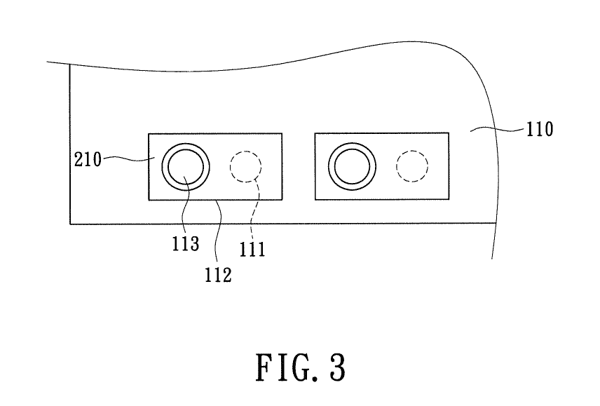

Next, refer to FIG. 3, wherein a diagram of a local structure in the die 110 according to the first embodiment of the present invention is shown. There are provided with a variety of circuit components or metal leads on the upper surface of the die 110, and the connection pad 112 and the solder bump 113 are also disposed on the upper surface of the die 110. The connection pad 112 is connected to the through hole 111 (indicated by the dotted line), while the solder bump 113 is configured on the connection pad 112 and located around the through hole 111. The number of connection structures (including the connection pad 112, through hole 121 and solder bump 113) is determined by the signal or the number of pins installed on the die 110. It should be noted that FIG. 3 depicts only one possible embodiment of the present invention and the structure of the die 110˜140 is by no means limited to FIG. 3.

### Second Embodiment

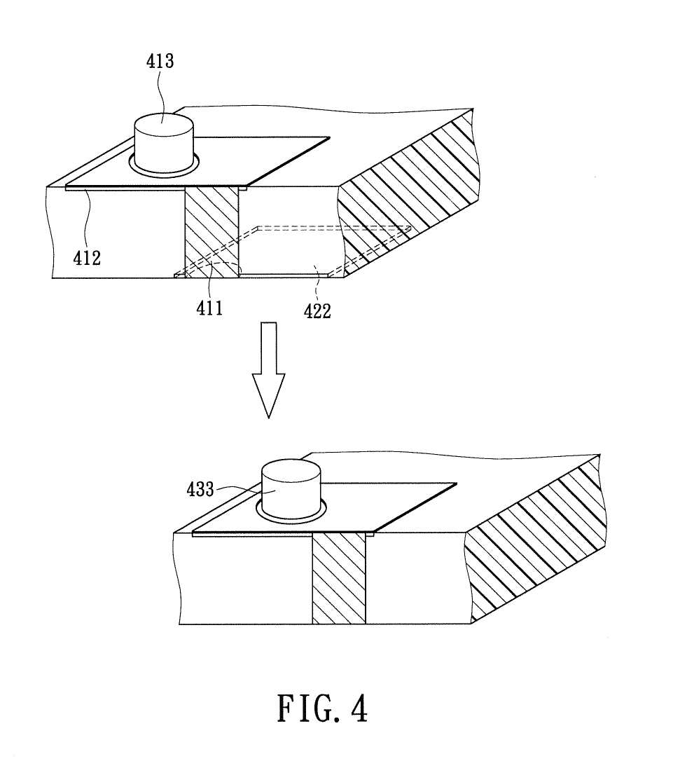

Refer now to FIG. 4, wherein a diagram of the connection structure according to a second embodiment of the present invention is shown. In FIG. 4, a connection pad 412 and 422 is respectively disposed on the upper and lower surfaces of the die, wherein the connection pad 412 is connected to the through hole 411 with the solder bump 413 installed thereon, while the connection pad 422 is connected to the other end of the through hole 411. Since the connection pad 422 has a larger area, it is hence more convenient to align in position to the solder bump 433 disposed on the lower die thereby elevating the process yield rate and alignment precision. The connection structure shown in FIG. 4 can be directly applied on the dies 110˜140 described in FIG. 1 so as to simplify the manufacture process and increase the process yield rate. Through the aforementioned descriptions on the present embodiment, those skilled ones in the art are capable of inferring to other possible implementations, and therefore the descriptions are omitted.

In summary, the present invention utilizes the silicon through-silicon via technology in conjunction with a structure design comprising connection pads and solder bumps thereby improving the process yield rate of the stack-based chip structure and simplifying the process thereof.

Although the preferred embodiments of the present invention have been disclosed as the aforementioned descriptions, the characteristics of the present invention are not restricted thereto. All changes, alternations, or modifications conveniently considered by those skilled in the art without departing from the spirit and scope of the present invention are deemed to be encompassed within the scope of the present invention delineated by the following claims.

What is claimed is:

1. A chip stacked structure, comprising:
a first die having a plurality of first connection structures, each of the first connection structures having a first through hole, a first connection pad and a first solder bump, wherein the first connection pad is connected to the first through hole and the first solder bump is disposed on the first connection pad and located around the first through hole; and
a second die, stacked on a top of the first die, having a plurality of second connection structures, each of the second connection structures having a second through hole;
wherein each second through hole in the second die is respectively aligned and bonded to each first solder bump on surface of the first die.

2. The chip stacked structure according to claim 1, wherein each second connection structure further comprises a second connection pad and a second solder bump, the second connection pad is connected to the second through hole, and the second solder bump is disposed on the second connection pad and located around the second through hole.

3. The chip stacked structure according to claim 2, wherein an upper surface of the first die faces toward a lower surface of the second die, the first connection pad and the first solder bump are located on the upper surface of the first die, and the second connection pad and the second solder bump are located on an upper surface of the second die.

4. The chip stacked structure according to claim 1, wherein the positions of the first connection structures and the second connection structures are mutually interlaced.

5. The chip stacked structure according to claim 1, wherein each first connection structure and each second connection structure are symmetrical in structure.

6. The chip stacked structure according to claim 1, wherein the first through hole and the second through hole are filled with a conductive material.

7. The chip stacked structure according to claim 1, wherein the second through hole and the first solder bump are bonded by a heating process.

8. The chip stacked structure according to claim 1, wherein the first connection structures are located on the edge of the first die, the second connection structures are located on the edge of the second die, and the first connection structures respectively correspond to the second connection structures.

9. The chip stacked structure according to claim 1, wherein each first connection structure further comprises a third connection pad, wherein the first connection pad is disposed on an upper surface of the first die, the third connection pad is disposed on a lower surface of the first die, and the third connection pad is connected to the first through hole.

10. The chip stacked structure according to claim 1, wherein the first connection pad is covered with a solder mask layer which has an opening for placing the solder bump.
